(19) United States
(12) Patent Application Publication
(10) Pub. No.: US 2018/0158849 A1
(43) Pub. Date: Jun. 7, 2018

(54) PHOTODIODE DEVICE AND METHOD OF MANUFACTURE

(71) Applicant: X-FAB Semiconductor Foundries AG, Erfurt (DE)

(72) Inventors: Christoph Henkel, Erfurt (DE); Daniel Gäbler, Apolda (DE); Alexander Zimmer, Rudolstadt (DE)

(73) Assignee: X-FAB Semiconductor Foundries AG, Erfurt (DE)

(21) Appl. No.: 15/831,597

(22) Filed: Dec. 5, 2017

(30) Foreign Application Priority Data
Dec. 5, 2016 (GB) 1620675.7

(51) Int. Cl. H01L 27/144; H01L 31/101; H01L 31/11; H01L 31/0352; H01L 31/18

(52) U.S. Cl. CPC H01L 27/1443; H01L 31/1013; H01L 31/1804; H01L 31/035272; H01L 31/11

(57) ABSTRACT

A method of manufacturing a photodiode device comprises providing a stacked photodiode device. The stacked photodiode device comprises a substrate having a first conductivity type, a first well having a second conductivity type, within the substrate, and a second well having the first conductivity type, within the first well. The stacked photodiode device is modified by implanting a multiplication implant within the first well, so as to manufacture an avalanche photodiode device. A photodiode device comprising one or more stacked photodiodes and one or more avalanche photodiodes may be manufactured by providing two or more stacked photodiodes and modifying at least one of the stacked photodiodes by implanting a multiplication implant.

### CROSS-REFERENCE TO RELATED APPLICATION

This application is based upon and claims the benefit of priority from United Kingdom Patent Application No. 1620675.7, filed Dec. 5, 2016, the entire contents of which are incorporated herein by reference

### TECHNICAL FIELD

The present invention relates to photodiode devices and methods of their manufacture. Specifically, but not exclusively, the present invention relates to methods of manufacturing avalanche photodiodes.

### BACKGROUND

Optical sensors, such as photodiodes, are widely used in integrated complementary metal oxide semiconductor (CMOS) devices for conversion of light into an electrical current with an analogue or a digital signal output. Photodiode applications may include light meters, smoke detectors and optical communications.

Typically, a standard photodiode is formed by doping a silicon wafer to alter its electrical properties and to produce regions of different electrical conductivity, referred to as p-type and n-type regions. N-type (negative) regions contain mostly free electrons while p-type (positive) regions contain mostly “holes” (i.e. the absence of an electron). Where these regions meet a p-n junction is formed. An incoming photon of sufficient energy generates an electron-hole pair which is separated by the internal electrical field in the p-n junction, causing electrical current to flow. Such photodiodes may consist of standard CMOS implants and may have a wavelength dependent responsivity signal.

Stacked photodiodes can be used in order to obtain spectral information regarding incoming light. Stacked photodiodes are provided with multiple interleaved p-n junctions. In a typical top-illuminated CMOS stacked photodiode, light of shorter wavelength (such as visible light) is absorbed in the upper p-n junction, due to the larger absorption coefficient of silicon for light of short wavelength. Light of longer wavelength (such as infrared light) is absorbed in the larger volume of the lower p-n junction of the stacked photodiode. Each junction or independent photodiode of the stacked photodiode therefore responds to different wavelengths of light.

Stacked photodiodes have many applications, such as the ambient light sensor described in US2014263972A1 and the multispectral imager disclosed in US20150129747A1. US2014263972A1 also discloses a “dark” stacked photodiode structure, fully covered by metal layers to block all incident light, which may be used in conjunction with the stacked photodiode structure to improve accuracy at low ambient lights levels. US20150129747A1 further discloses the use of a colour filter array to provide wavelength discrimination between the visible and infrared detecting photodiodes.

Another type of photodiode is the avalanche photodiode device (APD). An APD allows for internal amplification of the electron-hole pair production by application of a high electrical field inside the p-n junction. This high field is generated by the application of a sufficiently large voltage between the cathode and anode of the avalanche photodiode, i.e. by reverse-biasing the photodiode. The electrons produced by an incoming photon are accelerated such that they produce further electron hole pairs through impact ionisation. In this way, a single photon can typically produce hundreds or thousands of electrons, producing a gain or multiplication effect of around ×100 or ×1000 in comparison with a normal photodiode. An APD operating in a linear mode can therefore provide a much higher level of sensitivity than a stacked photodiode. The doping level of the p-n junction in an APD is specifically designed to produce this response.

If the reverse-bias voltage applied to the avalanche photodiode is high enough to produce the above “avalanche” effect, but still below a threshold level, then the avalanche produced by the photon of light will eventually die down again due to friction losses. However, if the reverse-bias voltage increases beyond a critical or breakdown level, the electrical field in the device is high enough so that one photon can fire the “avalanche”. When operated with a reverse-bias voltage which is high enough above the breakdown voltage, an APD can operate in Geiger-mode as a single-photon avalanche photodiode (SPAD) with gain levels of up to ×10⁶. In other words, an SPAD is sensitive enough to detect single photons of incident light. Again, the p-n junction is designed to be able to operate at these gain levels and a quenching circuit is typically required to reduce the voltage to the breakdown level. Quenching may be passive or active. Passive quenching includes the use of a series resistor to the APD, while active quenching includes the use of a transistor to control the voltage of the APD.

Examples of avalanche photodiodes are described in U.S. Pat. No. 3,886,579 and WO2012032353A2. U.S. Pat. No. 7,547,872 discloses an integrated circuit comprising an array of single-photon avalanche diodes, and U.S. Pat. No. 8,779,543B2 describes a device having an avalanche photo diode and includes a method for sensing photons. “Epitaxial silicon single photon detector with reduced carrier diffusion effect and picosecond resolution”, M. Ghioni/Cova et al. IEDM 1987, describes a single-photon avalanche diode (SPAD).

### SUMMARY

The inventors have appreciated that additional filters or components may be required when using conventional stacked photodiodes to measure an exact ambient light level, for example. This adds costs and complexity to the photodiode device and may cause such a device to require a larger footprint.

The inventors have further appreciated that an avalanche photodiode, and in particular a single-photon avalanche photodiode, can provide a much higher degree of sensitivity than a stacked photodiode, and that it would be beneficial to be able to provide the functionality of both a stacked and an avalanche photodiode in the same device.

Aspects of the invention are set out in the independent claims.

### BRIEF DESCRIPTION OF THE DRAWINGS

Some embodiments of the invention will now be described by way of example only and with reference to the accompanying drawings, in which:

FIG. 1 shows a representation of a stacked photodiode device;

FIG. 2 shows a representation of the stacked photodiode device of FIG. 1 undergoing an implantation process;

FIG. 3 shows a representation of the stacked photodiode device of FIG. 1 after implantation;

FIG. 4 illustrates a method of manufacturing a photodiode device;

FIG. 5 shows a representation of an array comprising stacked and avalanche photodiodes devices;

FIG. 6 illustrates the array of FIG. 5 from above; and

FIG. 7 illustrates a method of manufacturing the array.

### DETAILED DESCRIPTION

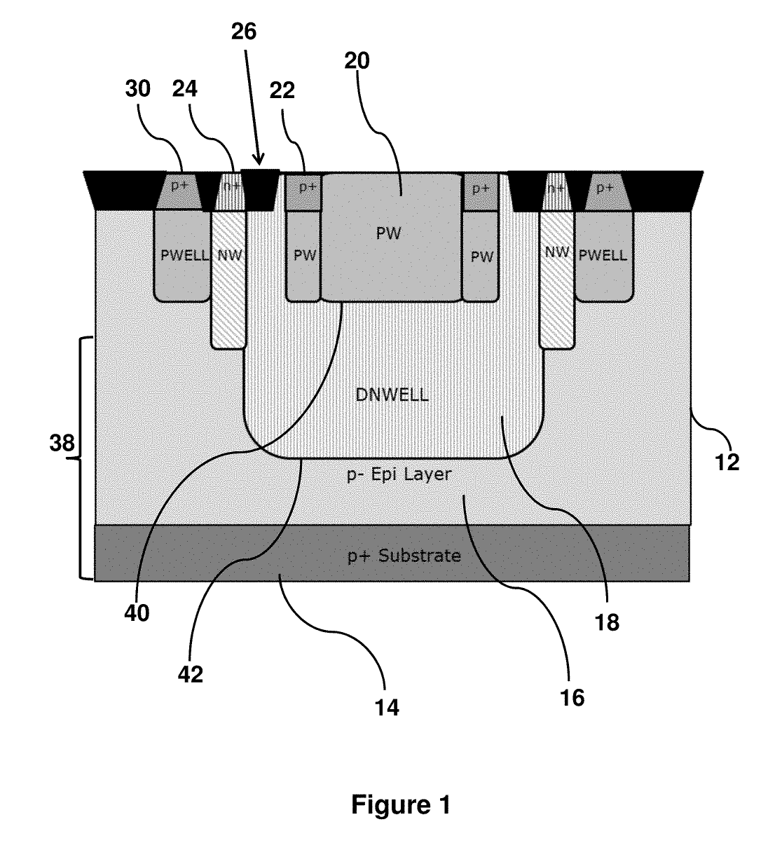

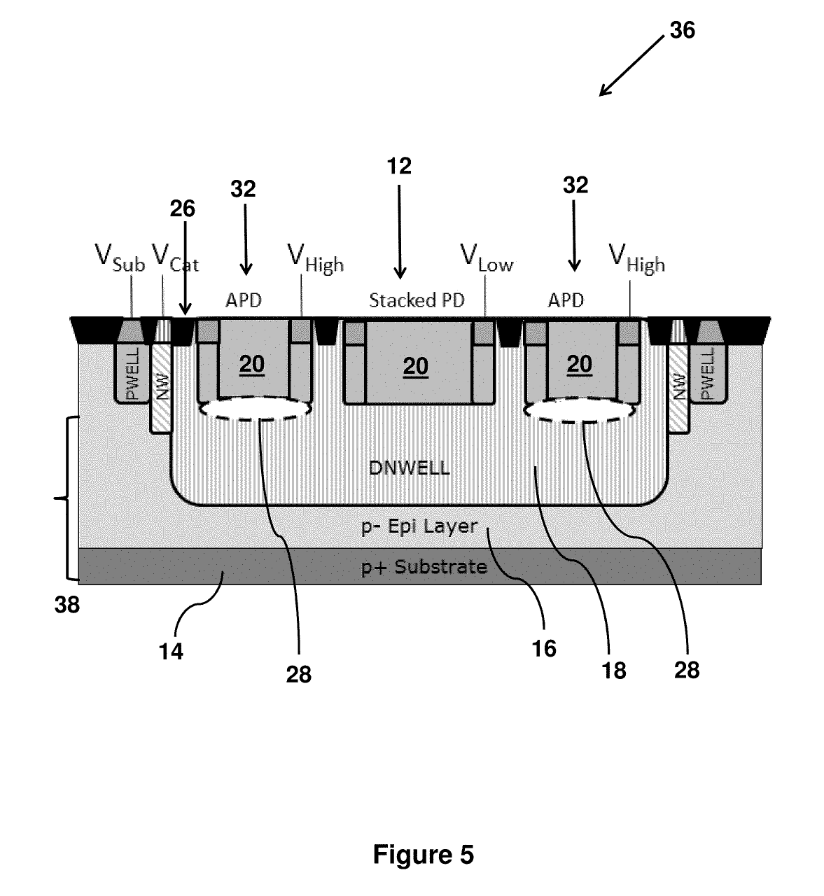

Described herein with reference to FIGS. 1 to 4 is a process by which the functionality of a stacked photodiode and an avalanche photodiode are combined in the same diode device and/or on the same silicon wafer. Further described with reference to FIGS. 5, 6 and 7 is an array comprising both stacked and avalanche photodiode functionality and a method of manufacture thereof.

FIG. 1 illustrates a stacked photodiode device 12 provided with standard CMOS implants. The structure of the device 12 comprises a substrate, generally indicated at 38, having a first conductivity type, a first well 18 having a second conductivity type, located within the substrate, and a second well 20 having the first conductivity type, located within the first well 18. In this example, the first well 18 is a DNWELL and the second well 20 is a stacked PWELL. A PWELL is a p-type region, while an NWELL is an n-type region. A DNWELL is an n-well layer which is implanted deeper down in the semiconductor structure than a normal n-well. The substrate comprises a p+ substrate 14, over which is deposited a p− epi (epitaxial) layer 16. Methods of manufacture of a stacked photodiode device 12, as described above, are known in the art.

The device 12 is further provided with electrical contacts, comprising a cathode (DNWELL) 24, an anode (PWELL) 22 and substrate contact (p− Epi) 30. The electrical contacts may be formed by diffusing p-type and n-type impurities into the diode structure. In this example, the electrical contacts 22, 24 are separated by a shallow trench isolation (STI) virtual guard ring 26.

The stacked photodiode device 12 illustrated in FIG. 1 comprises two p-n junctions 40, 42, one 42 between the p− epi layer 16 and the DNWELL 18, and one 40 between the DNWELL 18 and the PWELL 20.

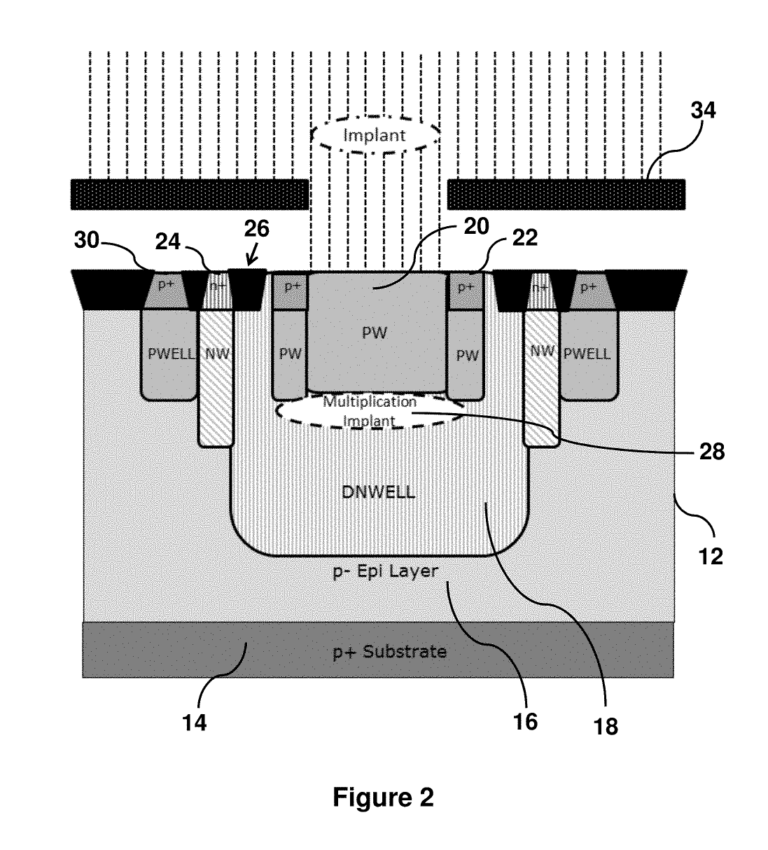

FIG. 2 illustrates a process whereby the stacked photodiode device 12 of FIG. 1 receives a multiplication implant 28. The process comprises modifying the stacked photodiode device 12 by implanting a multiplication implant 28 within the first well 18 (the DNWELL). The process is typically a standard doping process followed by annealing, and is controlled using a one layer mask 34. Properties of the implant 28 are selected such that the stacked photodiode device 12 can operate as an avalanche photodiode on application of a suitable reverse bias voltage. The implant 28 is defined by the dose, energy and angle at which the ions are implanted. The energy of the ions and angle of implantation determines the depth to which the ions penetrate. In a non-limiting example, the dose (i.e. the total amount of material implanted) is chosen such that the breakdown voltage is in the range of 14 to 20 V reverse bias.

In this context, the term “multiplication implant” refers to an implant which creates a single multiplication or acceleration region at an appropriate location within the photodiode device. In other embodiments, one or more implants may be used to create a single multiplication region within the photodiode device. The one or more implants may be implanted in a single step.

The implant 28 is configured to be located within the DNWELL 18, and adjacent to the junction with the PWELL 20 (the p-n junction). In order to increase effectiveness, the minimum implant 28 size is generally defined by the active area of the photodiode. Using a smaller implant size than this minimum implant size may still result in a suitable device but the effectiveness would be reduced as it would be expected that some photons will not be multiplied. The maximum implant 28 size is limited by the need to avoid edge breakdown.

The multiplication implant 28 creates an avalanche or multiplication region within the stacked photodiode 12 structure, and hence an avalanche photodiode device is formed. To achieve this, the dose of the implant 28 should be high enough to produce, upon application of reverse bias, an electrical field of, for example, greater than 3.5×10⁵ volts per cm (V/cm) in the avalanche region, i.e. corresponding to the region of the p-n junction between the PWELL 20 and DNWELL 18.

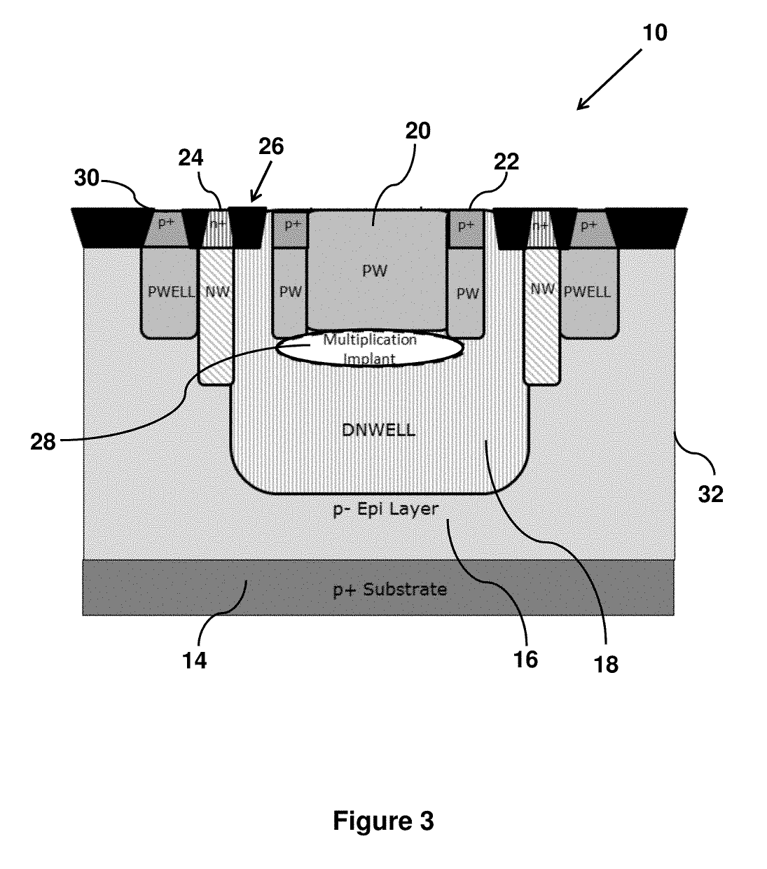

FIG. 3 illustrates the photodiode device of FIG. 2 after implantation is complete. The device 10 formed by the implantation process now comprises an avalanche photodiode 32.

It will be appreciated that the device 10 functions as an avalanche photodiode 32 only when a suitable reverse bias is applied. A suitable reverse bias may be in the range 14 to 20 V, for example. This has the advantage that the device 10 can function as a normal stacked photodiode 12 until the application of sufficient reverse bias. If the reverse bias sufficiently exceeds the breakdown voltage then the device 10 can operate as the second type of avalanche photodiode described above, i.e. a single photon avalanche diode (SPAD), capable of detecting single photons. A suitable circuit and quenching is used for SPAD operation. As discussed above, quenching may be passive or active. Effectively, increasing the reverse bias voltage increases the sensitivity of the device 10. Upon sufficient decrease of the reverse bias voltage (for example, a decrease down to around 2 V reverse bias) the device 10 will resume operation as a simple stacked photodiode device 12.

The inventive method of manufacture described herein therefore provides a single device 10 which is operable as a stacked photodiode, an avalanche photodiode or an SPAD. The stacked photodiode 12 and the avalanche photodiode 32 share the same guard ring 26 periphery and contact structure. Both stacked photodiode 12 and avalanche photodiode 32 devices share a bottom p-n junction (the junction between the p− epi layer 16 and the DWELL 18) and identical parasitic capacitances and leakage current. In other words, apart from the multiplication implant 28 the layout of both devices 12, 32 is the same. The addition of the multiplication implant 28 has no effect upon the footprint of the original stacked photodiode 12.

Since the manufacturing process uses only a single mask implantation step and creates only a single multiplication region, the resulting device 10 can have a small footprint and a high fill factor. In one embodiment, the only additional step beyond the provision of the stacked photodiode device 12 is the single implantation step in order to form implant 28. The addition of only one further step to the standard process for manufacturing a stacked photodiode device keeps manufacturing costs down. The inventors envisage that an annealing step would normally be carried out after implantation of implant 28. However, since annealing is typically carried out as part of the stacked photodiode manufacturing process no separate, additional annealing step is required in relation to implant 28, i.e. the annealing of implant 28 can be carried out as part of the annealing that would normally be required during the manufacture of the stacked photodiode device. To this end, the annealing step (as part of the manufacture of the stacked photodiode device) is deferred until after the implantation step which forms implant 28.

A further benefit of the manufacturing process herein described is that the configuration of the multiplication implant 28 can be varied in order to produce avalanche photodiodes 32 having different breakdown characteristics, thus allowing different voltage application ranges, as required. Thus, the point at which the device 10 begins to function as an APD can be controlled.

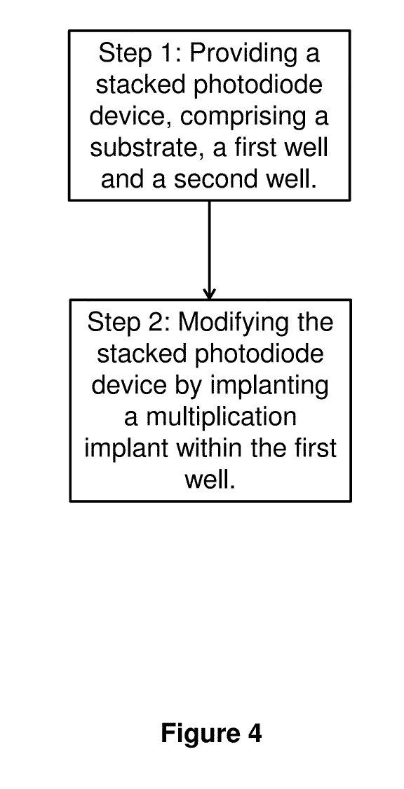

FIG. 4 illustrates a method of manufacturing a photodiode device, such as the device described with reference to FIG. 3. The method comprises the steps of:

Step 1: Providing a stacked photodiode device, the stacked photodiode device comprising: a substrate having a first conductivity type; a first well having a second conductivity type, within the substrate; and a second well having the first conductivity type, within the first well.

Step 2: Modifying the stacked photodiode device by implanting a multiplication implant within the first well, so as to manufacture an avalanche photodiode device.

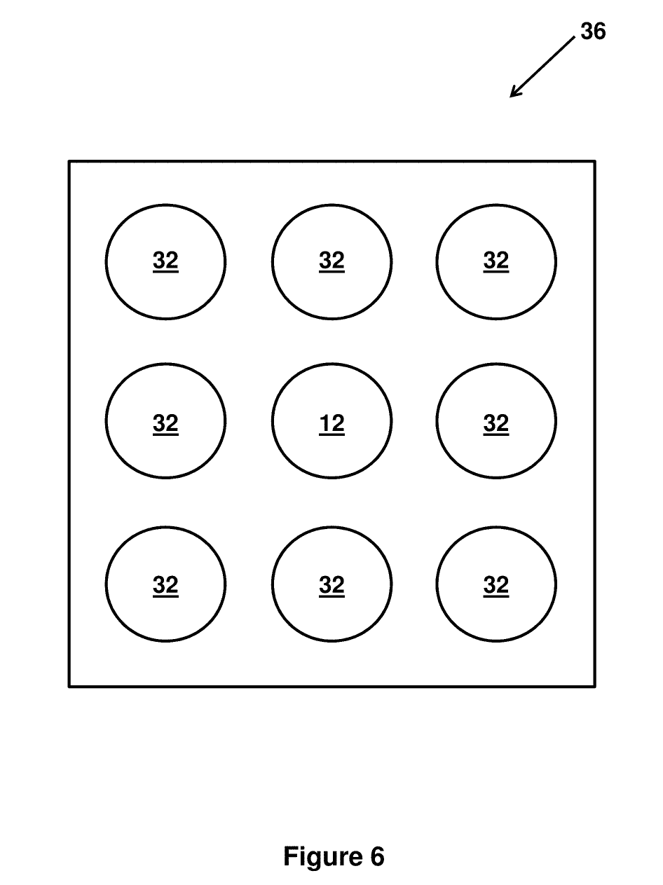

FIG. 5 illustrates an array 36 comprising stacked 12 and avalanche 32 photodiodes devices. The method of manufacture of the array 36, as illustrated in FIG. 6, comprises providing two or more stacked photodiode devices 12, each located within a common first well 18. This first well 18 is located on or within a substrate, the substrate having a first conductivity type and the first well 18 having a second conductivity type. The substrate in this example comprises a p+ substrate 14, over which is deposited a p− epi (epitaxial) layer 16. Each of the two or more stacked photodiodes 12 are provided with a respective second well 20 having the first conductivity type, and located within the first well 18.

The method further comprises modifying at least one of the stacked photodiode devices 12 by implanting a multiplication implant 28 within the first well 18 associated with the at least one stacked photodiode device 12 adjacent the respective second well 20, so as to manufacture at least one avalanche photodiode device 32. It will be appreciated that more than one stacked photodiode device 12 may be modified using this method, each being provided with its respective multiplication implant 28. In the array of FIG. 5 two stacked photodiodes devices have been modified. The method of implantation is substantially the same as described with reference to FIG. 2 above. In other embodiments, more than one multiplication implant may be implanted in order to create a single multiplication region associated with the at least one stacked photodiode device. As previously discussed, the avalanche photodiode 32 will only function as such when sufficient reverse bias is applied. All devices in the array may therefore still function as simple stacked photodiodes 12.

The array 36 of stacked 12 and avalanche 32 photodiode devices produced by the above-described method of manufacture share the same guard ring 26 periphery and bottom p-n junction. This may limit or reduce crosstalk between the avalanche photodiode devices 32. It will be appreciated that the implantation process as described above can be continued such that every other stacked photodiode 12 on the wafer is converted into an avalanche photodiode 32. Alternatively, stacked photodiode devices 12 formed upon the wafer can be converted to avalanche photodiode devices 32 as required so that, for example, every fifth stacked photodiode is provided with a multiplication implant and hence converted to be operable as an avalanche photodiode.

As illustrated in the plan view of FIG. 6, in one embodiment the array 36 comprises a central unmodified stacked photodiode device 12 surrounded by one or more avalanche photodiode devices 32. All of the photodiode devices are substantially circular in shape, although it will be appreciated that other configurations may be envisaged. Likewise, the array of photodiode devices does not need to have the same arrangement as the one shown in FIG. 6. The array itself may have a different overall shape and the distribution of stacked photodiode devices 12 and avalanche photodiode devices 32 within the array may differ from the one shown in FIG. 6.

An array 36 so produced can advantageously act as a photosensor or the like to detect the wavelength of incoming light using two or more separately optimized devices. In this way, the ambient light signal level can be (more) accurately determined without the need for additional filters or components.

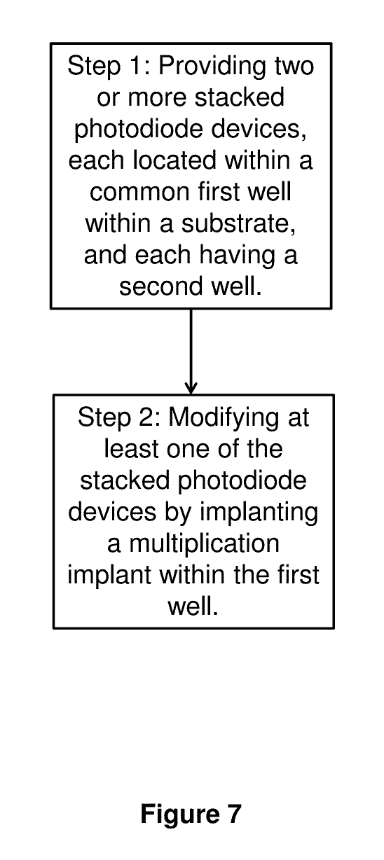

FIG. 7 illustrates a method of manufacturing a photodiode device comprising one or more stacked photodiodes and one or more avalanche photodiodes, such as the device described with reference to FIGS. 5 and 6. The method comprises the steps of:

Step 1: Providing two or more stacked photodiodes, each of the stacked photodiodes located within a common first well, the first well located on or within a substrate, the substrate having a first conductivity type and the first well having a second conductivity type; each of the two or more stacked photodiodes having a respective second well having the first conductivity type, within the first well.
Step 2: Modifying at least one of the stacked photodiodes by implanting a multiplication implant within the first well adjacent the respective second well, so as to manufacture an avalanche photodiode.

As discussed above, in further embodiments a single multiplication region may be created within a stacked photodiode by implanting more than one multiplication implant.

The term “device” as described herein may refer to an individual photodiode or may refer to a number of photodiodes of the same or different types located on the same wafer or otherwise associated with one another, depending upon the context.

Although the invention has been described in terms of certain embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. A method of manufacturing a photodiode device, the method comprising:
providing a stacked photodiode device, the stacked photodiode device comprising:
a substrate having a first conductivity type;
a first well having a second conductivity type, within the substrate; and
a second well having the first conductivity type, within the first well;
the method further comprising modifying the stacked photodiode device by implanting a multiplication implant within the first well, so as to manufacture an avalanche photodiode device.

2. The method according to claim 1, wherein implanting the multiplication implant comprises creating a single multiplication region within said first well.

3. The method according to claim 1, wherein implanting the multiplication implant comprises implanting the multiplication implant under the second well.

4. The method according to claim 1, further comprising controlling the implanting using a single mask.

5. The method according to claim 4, wherein modifying the stacked photodiode device consists in implanting the multiplication implant using said mask.

6. The method according to claim 1, wherein the implanting comprises doping and annealing.

7. The method according to claim 1, wherein the multiplication implant is configured to provide an electric field of at least 3.5×10⁵ V/cm at a junction of the first and second wells.

8. The method according to claim 1, wherein the photodiode device is configured to be selectively operable as either a stacked photodiode or an avalanche photodiode depending upon an applied voltage.

9. A method of manufacturing a photodiode device comprising one or more stacked photodiodes and one or more avalanche photodiodes, the method comprising:
providing two or more stacked photodiodes, each of the stacked photodiodes located within a first well, the first well located on or within a substrate, the substrate having a first conductivity type and the first well having a second conductivity type; each of the two or more stacked photodiodes having a respective second well having the first conductivity type, within the first well;
the method further comprising modifying at least one of the stacked photodiodes by implanting a multiplication implant within the first well associated with said at least one stacked photodiode adjacent the respective second well, so as to manufacture at least one avalanche photodiode.

10. The method according to claim 9, wherein the modifying comprises implanting a multiplication implant to create a single multiplication region within said first well.

11. The method according to claim 9, wherein the modifying comprises implanting a multiplication implant for each of said at least one of the stacked photodiodes.

12. The method according to claim 9, wherein implanting the multiplication implant comprises implanting the multiplication implant under the second well.

13. The method according to any claim 9, further comprising controlling the implanting using a single mask.

14. The method according to claim 9, wherein the implanting comprises doping and annealing.

15. The method according to claim 9, wherein the multiplication implant is configured to provide an electric field of at least 3.5×10⁵V/cm at a junction of the first and second wells.

16. The method according to claim 9, wherein the photodiode device is configured to be selectively operable as either an array of stacked photodiodes or an array of stacked and avalanche photodiodes depending upon an applied voltage.

17. A photodiode device comprising:
one or more stacked photodiodes;
one or more avalanche photodiodes; and
a first well;
the one or more stacked photodiodes and the one or more avalanche photodiodes being located within said first well.

18. A photodiode device according to claim 17, wherein the first well is located on or within a substrate, the substrate having a first conductivity type and the first well having a second conductivity type.

19. A photodiode device according to claim 18, wherein each of the one or more stacked photodiodes and each of the one or more avalanche photodiodes has a respective second well having the first conductivity type, within the first well.

20. A photodiode device according to claim 19, wherein each of the one or more avalanche photodiodes comprises a multiplication implant under the respective second well.

21. A photodiode device according to claim 20, wherein a material constituting the first well is in direct contact with the multiplication implant of the one or more avalanche photodiodes.

22. A photodiode device according to claim 20, wherein each of the multiplication implants is configured to provide an electric field of at least 3.5×10⁵ V/cm at a junction of the first and respective second wells.

23. A photodiode device according to claim 17, configured to be selectively operable as either an array of stacked photodiodes or a mixed array of stacked and avalanche photodiodes, depending upon an applied voltage.

24. The photodiode device of claim 17 wherein the photodiode device acts as a photosensor.
